(19) United States
(12) Patent Application Publication
(10) Pub. No.: US 2026/0143716 A1
(43) Pub. Date: May 21, 2026

(54) FORMATION OF CAPACITOR STRUCTURE USING A MULTI-LAYER MOLDING STACK AND A HARD MASK

(71) Applicant: Micron Technology, Inc., Boise, ID (US)

(72) Inventors: Hsiao Wei LIU, Taichung City (TW); Wei Ching HUANG, Taichung (TW); Yen Ling WENG, Taichung City (TW); Chien-Te WU, Taichung City (TW); Yi SHIA, Taichung City (TW); Kai Yen LO, Taichung City (TW)

(21) Appl. No.: 19/338,333

(22) Filed: Sep. 24, 2025

Related U.S. Application Data
(60) Provisional application No. 63/722,794, filed on Nov. 20, 2024.

(51) Int. Cl. H10B 53/30

(52) U.S. Cl. CPC H10B 53/30

(57) ABSTRACT

Implementations described herein relate to various structures, integrated assemblies, and memory devices. In some implementations, an integrated assembly includes a first capacitor electrode structure concentric, conductive layers that are vertically arranged. The integrated assembly includes a lattice structure, having at least three levels, that conjoins with the concentric, conductive layers, that is laterally arranged, and that provides mechanical support to the first capacitor electrode structure. The integrated assembly includes a capping structure on tips of the concentric, conductive layers, and a capacitor dielectric. The capacitor dielectric passes through the capping structure, passes through a support layer of the lattice structure, and conjoins with surfaces of the concentric, conductive layers. The integrated assembly includes a second capacitor electrode structure that conjoins with the capacitor dielectric.

### CROSS-REFERENCE TO RELATED APPLICATION

This Patent Application claims priority to U.S. Provisional Patent Application No. 63/722,794, filed on Nov. 20, 2024, entitled “FORMATION OF CAPACITOR STRUCTURE USING A MULTI-LAYER MOLDING STACK AND A HARD MASK,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to formation of a capacitor structure using a multi-layer molding stack and a hard mask.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 is a diagram illustrating example implementations of a capacitor structure described herein.

FIG. 3 is a flowchart of an example method of forming an integrated assembly or memory device having a capacitor structure described herein.

FIG. 4 is a flowchart of an example method of forming an integrated assembly or memory device having a capacitor structure described herein.

FIGS. 5A-5D are diagrammatic views showing formation of an example capacitor structure using an example process described herein.

FIGS. 6A-6D are diagrammatic views showing formation of a capacitor structure using an example process described herein.

FIG. 7 is a diagrammatic view of an example implementation described herein.

FIG. 8 is a diagrammatic view of an example memory device described herein.

### DETAILED DESCRIPTION

Memory technologies, such as dynamic random-access memory (DRAM) memory technologies, face escalating challenges as they advance in scaling and/or densities. In particular, design demands have pushed etching of features used to form capacitors to the edge of limitations associated with high aspect ratios (e.g., a depth versus width of a trench and/or a cavity). Overcoming these limitations is needed in order to achieve a desired capacitor size and/or storage capability, and can pose challenges such as under-etching, clogging during etching, etching features that do not satisfy critical dimension (CD) thresholds, and/or etching features with inconsistencies.

Some implementations described herein relate to a capacitor structure used in a semiconductor device. Techniques to form the capacitor structure, which may include a tri-level lattice structure (or a lattice structure that includes more than three levels) that supports concentric, conductive layers of the capacitor structure (e.g., an electrode structure), include using a hard mask over a multi-layer molding stack. In some implementations, the multi-layer molding stack includes multiple, temporary molding layers that are interspersed with layers of the lattice structure. The concentric, conductive layers may pass through the multi-layer molding stack.

A first technique to form the capacitor structure may include using a multi-layer molding stack including three temporary molding layers and removing the hard mask using a single chemical-mechanical planarization process. A second technique to form the capacitor structure may include using a multi-layer molding stack including two temporary molding layers, and using the hard mask in place of a third temporary molding layer used by the first technique. As part of the second technique, the hard mask is removed in several stages, including removing final portions of the hard mask using a vapor etching process.

In these ways, the techniques may enable formation of trenches, recesses, and/or cavities that satisfy one or more thresholds related to aspect ratios that govern etching operations used to remove the temporary molding layers and/or the hard mask. Satisfying the one or more thresholds may reduce a likelihood of under-etching, of clogging, of forming features that do not satisfy CD thresholds, and/or inconsistencies to improve a quality and/or reliability of the semiconductor device. Since the quality and/or the reliability of the semiconductor device are improved, an amount of resources used to support a market consuming the semiconductor device (e.g., raw materials, semiconductor manufacturing tools, labor, and/or computing resources) is reduced.

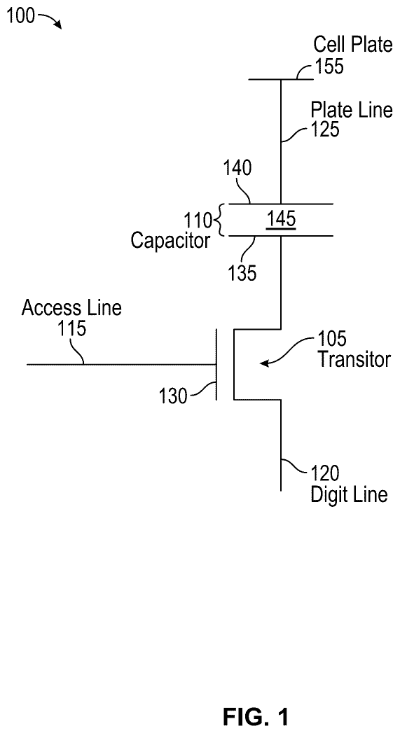

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

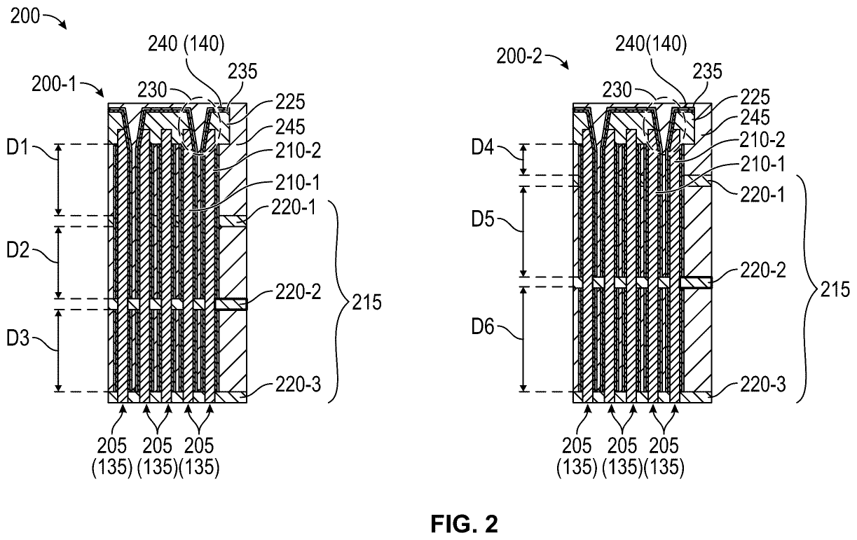

As described in greater detail in connection with FIGS. 2-8, in some implementations, an electrode of the capacitor 110 (e.g., the bottom electrode 135) is a pillar-like structure that includes concentric, conductive layers that are concentric and supported by a multi-level lattice structure, such as a tri-level lattice structure or a lattice structure with more than three levels. Techniques to form the electrode may include using a hard mask over a multi-layer molding stack, where the multi-layer molding stack includes layers of the lattice structure interspersed with multiple temporary molding layers. Based on a particular implementation, techniques to form the electrode may further include removing the hard mask using a chemical-mechanical planarization and/or a vapor etch operation.

As indicated above, FIG. 1 is provided as an example. Other examples may differ from what is described with respect to FIG. 1.

FIG. 2 is a diagram illustrating example implementations of a capacitor structure 200 described herein. The implementations include capacitor structure 200-1 (e.g., a first example implementation) and capacitor structure 200-2 (e.g., a second example implementation). The capacitor structure 200-1 and/or the capacitor structure 200-2 may correspond to the capacitor 110 of FIG. 1, including the bottom electrode 135, the top electrode 140, and the insulator 145.

As shown in the side section views of FIG. 2, a capacitor structure 200 (e.g., the capacitor structure 200-1 and/or the capacitor structure 200-2) may include an electrode structure 205 (e.g., a first electrode structure corresponding to the bottom electrode 135) that includes two or more concentric, conductive layers 210, including the concentric, conductive layer 210-1 and the concentric, conductive layer 210-2. Each of the concentric, conductive layers 210 may be an elongated cylinder, an elongated rectangular prism, or another suitable geometric shape that is distributed about a central (and vertical) axis. Each of the concentric, conductive layers 210 may be an electrical conductor and may comprise, consist of, or consist essentially of conductive material. As an example, the conductive material may comprise, consist of, or consist essentially of a metal nitride, such as titanium nitride or titanium silicon nitride. Alternatively, the conductive material may comprise, consist of, or consist essentially of a metal composition (e.g., a metal silicide, a metal carbide), a conductively-doped semiconductor material (e.g., conductively-doped silicon, conductively-doped germanium, and/or conductively-doped gallium arsenide), or another suitable conductive material, among other examples.

As further shown in FIG. 2, a capacitor structure 200 (e.g., the capacitor structure 200-1 and/or the capacitor structure 200-2) may include a tri-level lattice structure 215 that is laterally arranged and that conjoins with the concentric, conductive layers 210, including the concentric, conductive layer 210-1 and the concentric, conductive layer 210-2. The tri-level lattice structure 215 may include multiple support layers 220, including a support layer 220-1 (e.g., an upper support layer), a support layer 220-2 (e.g., a middle support layer), and a support layer 220-3 (e.g., a lower support layer). As shown, the middle support layer is between the upper support layer and the lower support layer. Each of the support layers 220 may mechanically support the concentric, conductive layers 210 during and/or after formation of a capacitor structure 200 (e.g., the capacitor structure 200-1 and/or the capacitor structure 200-2). Each of the support layers 220 may be an electrical insulator and may comprise, consist of, or consist essentially of insulative material. As an example, the insulative material may comprise, consist of, or consist essentially of silicon nitride. Alternatively, the insulative material comprise, consist of, or consist essentially of silicon dioxide or another suitable dielectric material, among other examples.

Although the capacitor structure 200 is shown as including a tri-level lattice structure 215 with three levels (e.g., exactly three levels), in some implementations, the capacitor structure 200 may include a lattice structure with more than three levels for additional mechanical support (e.g., depending on a height of the concentric, conductive layers 210). Thus, the capacitor structure 200 may include a lattice structure with three or more levels, and/or the lattice structure 215 may include three or more levels. If the lattice structure includes more than three levels or layers, the lattice structure may include an upper support layer, a lower support layer, and multiple middle support layers that are between the upper support layer and the lower support layer.

As further shown in FIG. 2, a capacitor structure 200 (e.g., the capacitor structure 200-1 and/or the capacitor structure 200-2) may include a capping structure 225 that is on and/or over tips of the concentric, conductive layers 210 and that includes a cavity 230 (e.g., a conduit, a passage way) that penetrates through the capping structure 225 between the concentric, conductive layers 210 (e.g., between the concentric, conductive layer 210-1 and the concentric, conductive layer 210-2). The capping structure 225 may electrically isolate the concentric, conductive layers 210, thereby ensuring functionality of a capacitor structure 200 (e.g., the capacitor structure 200-1 and/or the capacitor structure 200-2). The capping structure 225 may be an electrical insulator and include an insulative material. As an example, the insulative material may comprise, consist of, or consist essentially of silicon nitride. Alternatively, the insulative material may comprise, consist of, or consist essentially of silicon dioxide or another suitable dielectric material, among other examples.

As further shown in FIG. 2, a capacitor structure 200 (e.g., the capacitor structure 200-1 and/or the capacitor structure 200-2) may include a capacitor dielectric 235 that passes through the cavity 230 and through the support layer 220-1, and that includes portions over, on, and/or along surfaces of the concentric, conductive layers 210. The capacitor dielectric 235 may increase an ability of the capacitor structure 200 to store an electrical charge. The capacitor dielectric 235 may be an electrical insulator and may comprise, consist of, or consist essentially of a layer of an insulative material. The insulative material may comprise, consist of, or consist essentially of a high-k dielectric material such as hafnium oxide, zirconium oxide, aluminum oxide, or another suitable insulative material, among other examples.

As further shown in FIG. 2, a capacitor structure 200 may include an electrode structure 240 (e.g., a second electrode structure corresponding to the top electrode 140) that is over and/or on the capacitor dielectric 235 and conforms to surfaces of the capacitor dielectric 235. The electrode structure 240 may be an electrical conductor and may comprise, consist of, or consist essentially of a layer of a conductive material. As an example, the conductive material may comprise, consist of, or consist essentially of a metal nitride, such as titanium nitride or titanium silicon nitride. Alternatively, the conductive material may comprise, consist of, or consist essentially of a metal composition (e.g., a metal silicide, a metal carbide), a conductively-doped semiconductor material (e.g., conductively-doped silicon, conductively-doped germanium, and/or conductively-doped gallium arsenide), or another suitable conductive material, among other examples.

As shown in FIG. 2, a capacitor structure 200 (e.g., the capacitor structure 200-1 and/or the capacitor structure 200-2) may include an insulative fill 245. The insulative fill 245 may be over, on, and/or along surfaces of the support layers 220 and/or the electrode structure 240 to provide electrical isolation and ensure functionality of the capacitor structure 200. The insulative fill 245 may be an electrical insulator and may comprise, consist of, or consist essentially of insulative material. The insulative material may comprise, consist of, or consist essentially of silicon dioxide and/or silicon nitride, among other examples.

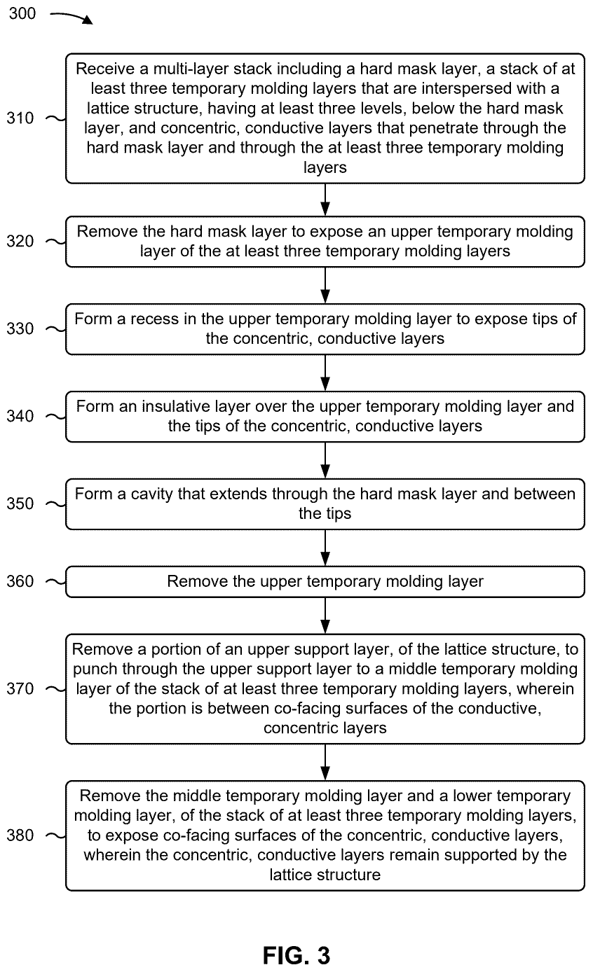

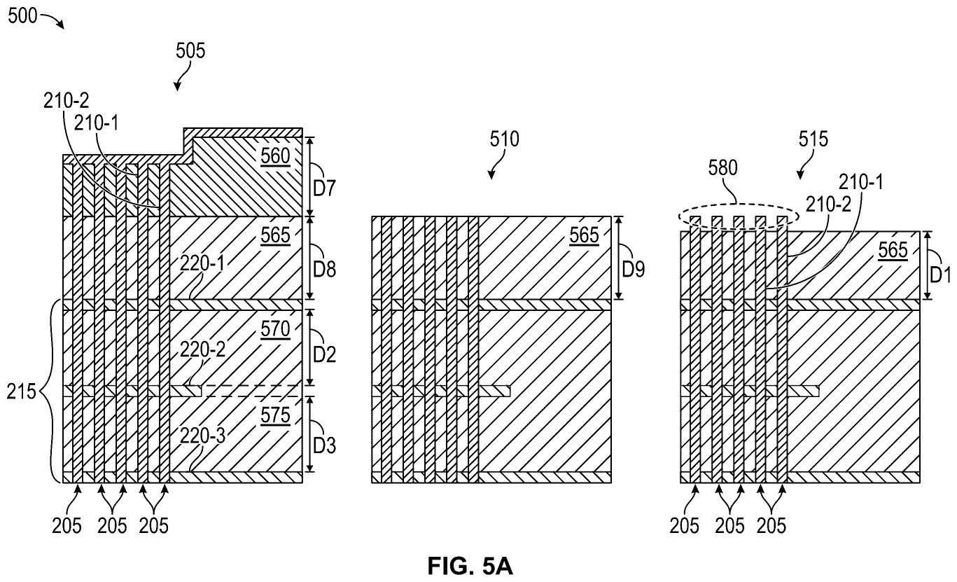

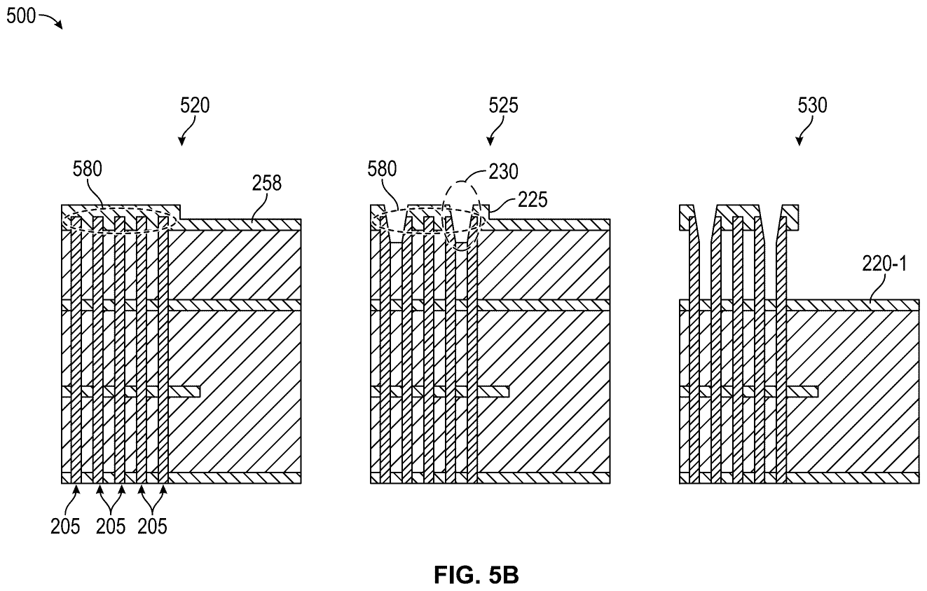

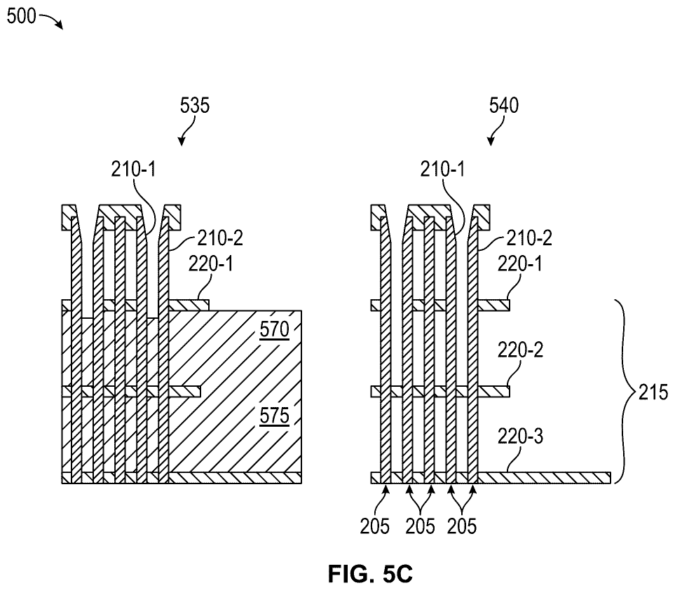

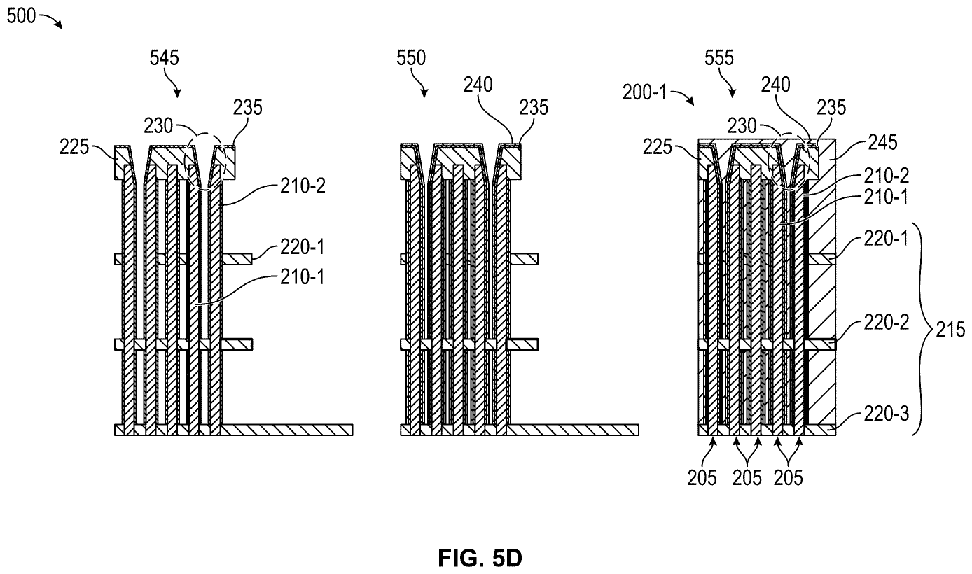

As described in greater detail in connection with FIGS. 3 and 5, a first method used to form the capacitor structure 200-1 may include using a hard mask over a first multi-layer molding stack that includes three temporary molding layers interspersed with the support layers 220-1 through 220-3. Using the first method, the capacitor structure 200-1 may be formed to have a distance D1 of approximately 2600 angstroms (Å) between the capping layer 225 and the support layer 220-1. Furthermore, the capacitor structure 200-1 may be formed to have a separation distance D2 of approximately 2600 Å between the support layer 220-1 and the support layer 220-2, and a separation distance D3 of approximately 2600 Å between the support layer 220-2 and the support layer 220-3. In other words, the separation distances D1, D2, and D3 may be a same approximate separation distance (e.g., within +/−5% of one another). In some implementations, the separation distances D1, D2, and/or D3 may effectuate formation of cavities and/or recesses in which the capacitor dielectric 235 is formed (e.g., cavities between the concentric, conductive layers 210-1 and 210-2) to have aspect ratios (e.g., height versus depth ratios) that are less than approximately 50.

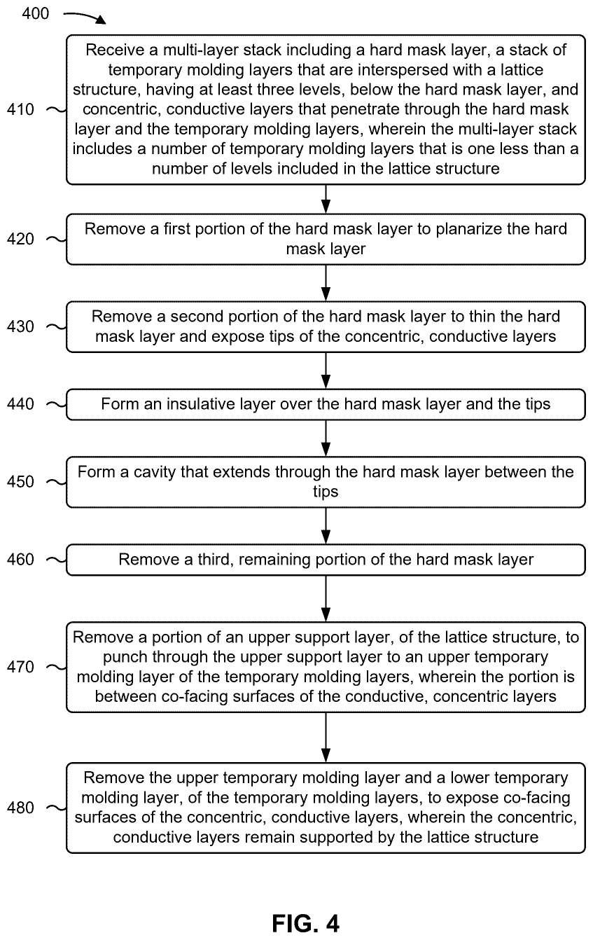

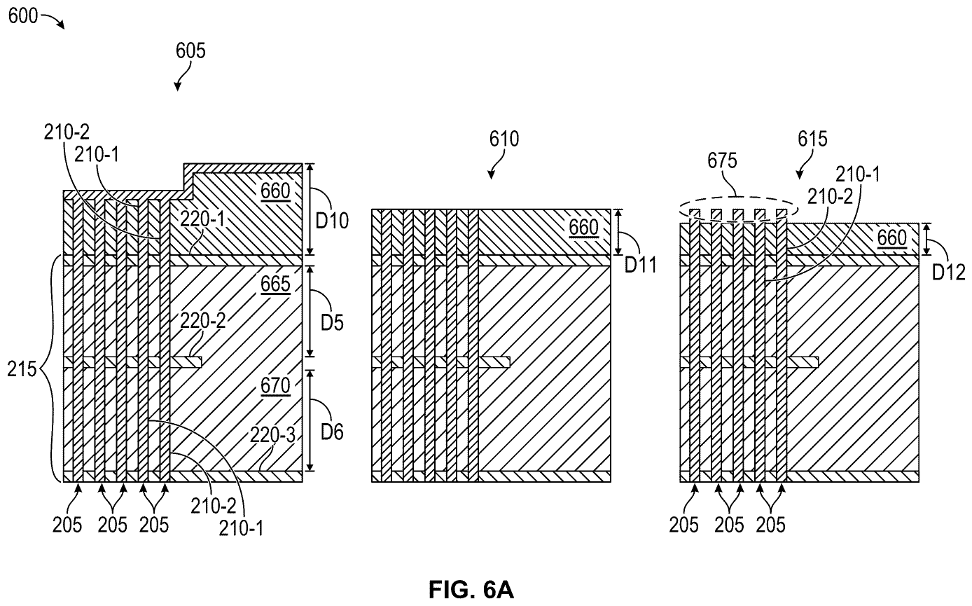

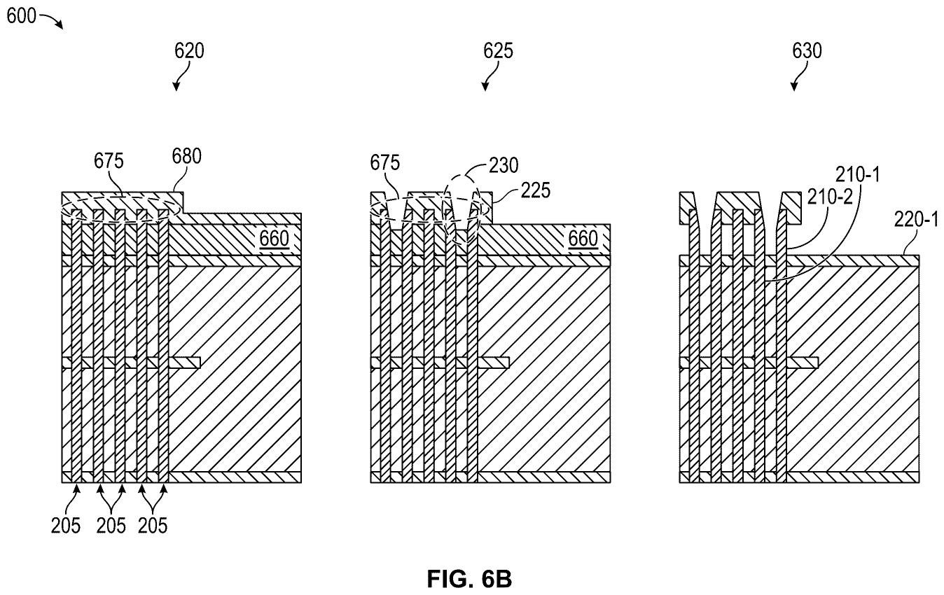

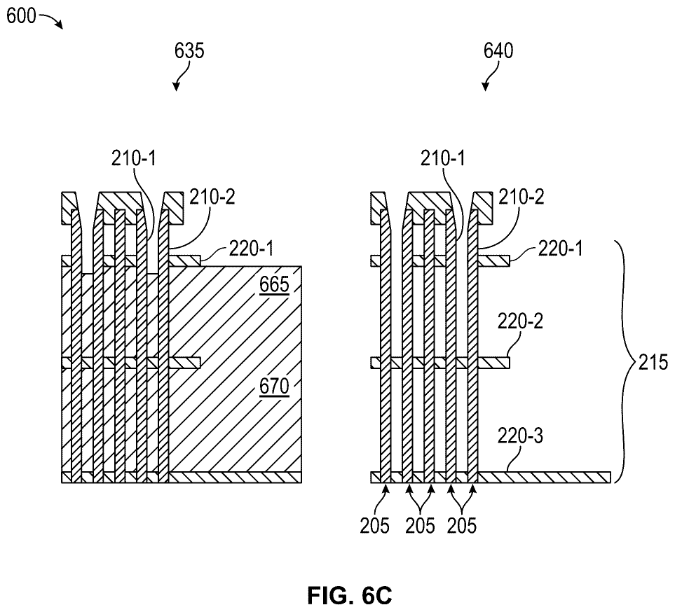

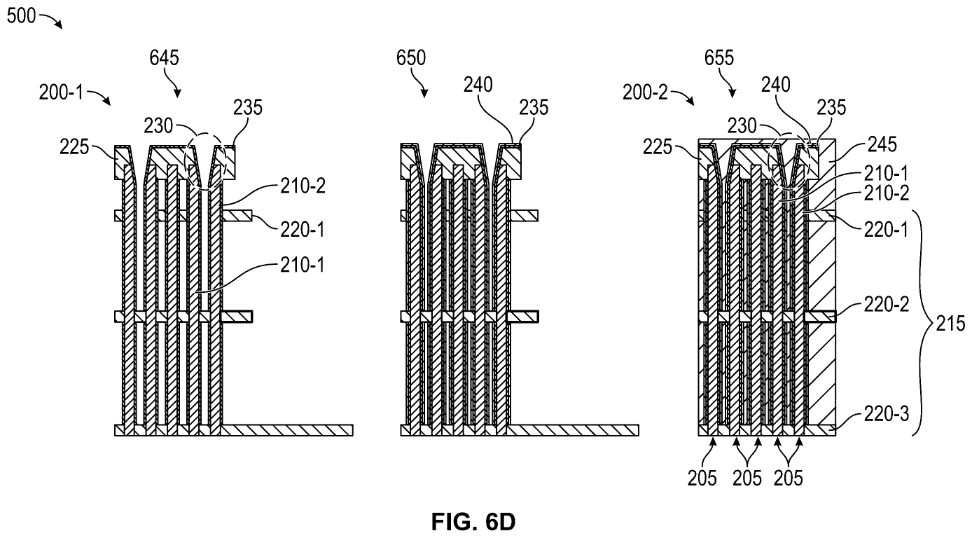

As described in greater detail in connection with FIGS. 4 and 6, a second method used to form the capacitor electrode 200-2 may include using a hard mask over a second multi-layer molding stack that includes two temporary molding layers

interspersed with the support layers 220-1 through 220-3. Using the second method, the capacitor electrode 200-2 may be formed to have a separation distance D4 of approximately 1500 Å between the capping layer 225 and the support layer 220-1, a separation distance D5 of approximately 2600 Å between the support layer 220-1 and the support layer 220-2, and a separation distance D6 of approximately 3100 Å between the support layer 220-2 and the support layer 220-3. In other words, the separation distances D4, D5, and D6 are different separation distances. Such distances may effectuate formation of cavities and/or recesses in which the capacitor dielectric 235 is formed (e.g., cavities between the concentric, conductive layers 210-1 and 210-2) to have aspect ratios (e.g., height-to-width ratios) that are less than approximately 40.

As indicated above, FIG. 2 is provided as an example. Other examples may differ from what is described with regard to FIG. 2.

As described in connection with FIGS. 1 and 2, and in some implementations, an integrated assembly (e.g., a semiconductor device including the memory cell 100) includes a first capacitor electrode structure (e.g., the electrode structure 205) concentric, conductive layers (e.g., the concentric, conductive layers 210-1 and 210-2) that are vertically arranged. The integrated assembly includes a tri-level lattice structure (e.g., the tri-level lattice structure 215) that conjoins with the concentric, conductive layers, that is laterally arranged, and that provides mechanical support to the first capacitor electrode structure. The integrated assembly includes a capping structure (e.g., the capping structure 225) on tips of the concentric, conductive layers, and a capacitor dielectric (e.g., the capacitor dielectric 235). The capacitor dielectric passes through the capping structure, passes through a support layer of the tri-level lattice structure, and conjoins with surfaces of the concentric, conductive layers. The integrated assembly includes a second capacitor electrode structure (e.g., the electrode structure 240) that conjoins with the capacitor dielectric.

As described in greater detail in connection with FIGS. 3-6D, techniques to form the integrated assembly include using different combinations of a hard mask over two or more temporary molding layers. The techniques enable formation of trenches, recesses, and/or cavities that satisfy one or more thresholds related to aspect ratios that govern etching operations used to remove temporary molding layers and/or the hard mask. Satisfying the one or more thresholds may reduce a likelihood of under-etching, of clogging, of forming features that do not satisfy CD thresholds, and/or inconsistencies to improve a quality and/or reliability of the integrated assembly. Since the quality and/or the reliability of the integrated assembly are improved, an amount of resources used to support a market consuming the integrated assembly (e.g., raw materials, semiconductor manufacturing tools, labor, and/or computing resources) is reduced.

FIG. 3 is a flowchart of an example method 300 of forming an integrated assembly or memory device having a capacitor structure described herein (e.g., the capacitor structure 200-1). In some implementations, and as described in greater detail in connection with FIGS. 5A-5D, one or more process blocks of FIG. 3 may be performed by various semiconductor manufacturing equipment.

As shown in FIG. 3, the method 300 may include receiving a multi-layer stack including a hard mask layer, a stack of at least three temporary molding layers that are interspersed with a lattice structure, having at least three levels (e.g., the tri-level lattice structure 215), below the hard mask layer, and concentric, conductive layers (e.g., the concentric, conductive layers 210-1 and 210-2) that penetrate through the hard mask layer and through the at least three temporary molding layers (block 310). As further shown in FIG. 3, the method 300 may include removing the hard mask layer to expose an upper temporary molding layer of the at least three temporary molding layers (block 320). As further shown in FIG. 3, the method 300 may include forming a recess in the upper temporary molding layer to expose tips of the concentric, conductive layers (block 330). As further shown in FIG. 3, the method 300 may include forming an insulative layer over the upper temporary molding layer and the tips of the concentric, conductive layers (block 340). As further shown in FIG. 3, the method 300 may include forming a cavity that extends through the hard mask layer and between the tips (block 350). As further shown in FIG. 3, the method 300 may include removing the upper temporary molding layer (block 360). As further shown in FIG. 3, the method 300 may include removing a portion of an upper support layer, of the lattice structure, to punch through the upper support layer to a middle temporary molding layer of the stack of at least three temporary molding layers, wherein the portion is between co-facing surfaces of the conductive, concentric layers (block 370). As further shown in FIG. 3, the method 300 may include removing the middle temporary molding layer and a lower temporary molding layer, of the stack of at least three temporary molding layers, to expose co-facing surfaces of the concentric, conductive layers, wherein the concentric, conductive layers remain supported by the lattice structure (block 380).

The method 300 may include additional aspects, such as any single aspect or any combination of aspects described below and/or in connection with one or more other methods described elsewhere herein.

In a first aspect, at least one of the hard mask layer includes boron-doped carbon, the upper temporary molding layer includes tetraethyl orthosilicate, the middle temporary molding layer includes tetraethyl orthosilicate, or the lower temporary molding layer includes boron phosphosilicate glass.

In a second aspect, alone or in combination with the first aspect, the hard mask layer includes boron-doped carbon.

In a third aspect, alone or in combination with one or more of the first and second aspects, the upper temporary molding layer includes tetraethyl orthosilicate, the middle temporary molding layer includes tetraethyl orthosilicate, and the lower temporary molding layer includes boron phosphosilicate glass.

In a fourth aspect, alone or in combination with one or more of the first through third aspects, removing the hard mask layer includes using a chemical-mechanical planarization operation that removes an entirety of the hard mask layer and portions of the conductive, concentric layers.

In a fifth aspect, alone or in combination with one or more of the first through fourth aspects, forming the cavity includes forming a patterned mask over the hard mask layer, and etching the hard mask layer using the patterned mask to remove portions of the hard mask layer through openings in the patterned mask.

In a sixth aspect, alone or in combination with one or more of the first through fifth aspects, there are exactly three temporary molding layers in the multi-layer stack, and the lattice structure has exactly three levels.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the capacitor structure 200-1 integrated assembly that includes the capacitor structure 200-1, any part described herein of the capacitor structure 200-1, and/or any part described herein of an integrated assembly that includes the capacitor structure 200-1. For example, the method 300 may include forming the memory cell 100 of FIG. 1.

FIG. 4 is a flowchart of an example method 400 of forming an integrated assembly or memory device having a capacitor structure described herein (e.g., the capacitor structure 200-2). In some implementations, and as described in greater detail in connection with FIGS. 6A-6D, one or more process blocks of FIG. 4 may be performed by various semiconductor manufacturing equipment.

As shown in FIG. 4, the method 400 may include receiving a multi-layer stack including a hard mask layer, a stack of temporary molding layers that are interspersed with a lattice structure, having at least three levels, below the hard mask layer, and concentric, conductive layers that penetrate through the hard mask layer and the temporary molding layers, wherein the multi-layer stack includes a number of temporary molding layers that is one less than a number of levels included in the lattice structure (block 410). As further shown in FIG. 4, the method 400 may include removing a first portion of the hard mask layer to planarize the hard mask layer (block 420). As further shown in FIG. 4, the method 400 may include removing a second portion of the hard mask layer to thin the hard mask layer and expose tips of the concentric, conductive layers (block 430). As further shown in FIG. 4, the method 400 may include forming an insulative layer over the hard mask layer and the tips (block 440). As further shown in FIG. 4, the method 400 may include forming a cavity that extends through the hard mask layer between the tips (block 450). As further shown in FIG. 4, the method 400 may include removing a third, remaining portion of the hard mask layer (block 460). As further shown in FIG. 4, the method 400 may include removing a portion of an upper support layer, of the lattice structure, to punch through the upper support layer to an upper temporary molding layer of the temporary molding layers, wherein the portion is between co-facing surfaces of the conductive, concentric layers (block 470). As further shown in FIG. 4, the method 400 may include removing the upper temporary molding layer and a lower temporary molding layer, of the temporary molding layers, to expose co-facing surfaces of the concentric, conductive layers, wherein the concentric, conductive layers remain supported by the lattice structure (block 480).

The method 400 may include additional aspects, such as any single aspect or any combination of aspects described below and/or in connection with one or more other methods described elsewhere herein.

In a first aspect, at least one of the hard mask layer includes boron-doped carbon, the upper temporary molding layer includes tetraethyl orthosilicate, or the lower temporary molding layer includes boron phosphosilicate glass.

In a second aspect, alone or in combination with the first aspect, the hard mask layer includes boron-doped carbon.

In a third aspect, alone or in combination with one or more of the first and second aspects, the upper temporary molding layer includes tetraethyl orthosilicate and the lower temporary molding layer includes boron phosphosilicate glass.

In a fourth aspect, alone or in combination with one or more of the first through third aspects, removing the first portion of the hard mask layer includes using a chemical-planarization operation that buffs the hard mask layer and planarizes the hard mask layer.

In a fifth aspect, alone or in combination with one or more of the first through fourth aspects, removing the second portion of the hard mask layer includes using a wet etch operation, a plasma-based etch operation, or an ion-based etch operation to remove the second portion.

In a sixth aspect, alone or in combination with one or more of the first through fifth aspects, removing the third, remaining portion of the hard mask layer includes using a vapor-based etch operation to remove the third, remaining portion.

In a seventh aspect, alone or in combination with one or more of the first through sixth aspects, there are exactly two temporary molding layers in the multi-layer stack, and the lattice structure has exactly three levels.

Although FIG. 4 shows example blocks of the method 400, in some implementations, the method 400 may include additional blocks, fewer blocks, different blocks, or differently arranged blocks than those depicted in FIG. 3. In some implementations, the method 400 may include forming the capacitor structure 200-2 integrated assembly that includes the capacitor structure 200-2, any part described herein of the capacitor structure 200-2, and/or any part described herein of an integrated assembly that includes the capacitor structure 200-2. For example, the method 400 may include forming the memory cell 100 of FIG. 1.

FIGS. 5A-5D are diagrammatic views showing formation of the capacitor structure 200-1 using an example process 500. The process 500 includes stages 505, 510,. 555. In some implementations, the example process 500 described below in connection with FIGS. 5A-5D may correspond to the method 300 and/or one or more blocks of the method 300. However, the process described below is an example, and other example processes may be used to form the structure capacitor structure 200-1, an integrated assembly that includes the structure capacitor structure 200-1, and/or one or more parts of the structure capacitor structure 200-1 and/or the integrated assembly.

As shown in FIG. 5A, and at stage 505, the process 500 may include receiving a multi-layer stack including a hard mask layer 560. Below the hard mask layer 560, the multi-layer stack may include the tri-level lattice structure 215, including the support layers 220-1 through 220-3. Furthermore, the multi-layer stack may include a temporary molding layer 565, a temporary molding layer 570, and a temporary molding layer 575 (e.g., three temporary molding layers) that are interspersed with the tri-level lattice structure 215 (e.g., interspersed with the support layers 220-1 through 220-3). The multi-layer stack may include the electrode structure 205 including the concentric, conductive layers 210-1 and 210-2 that penetrate through the hard mask layer 560, the temporary molding layer 565, the temporary molding layer 570, and the temporary molding layer 575.

Although the multi-layer stack is shown as including a tri-level lattice structure having three levels (e.g., exactly three levels), in some implementations, the multi-layer stack may include a lattice structure that includes more than three levels. Thus, the multi-layer stack may include a lattice structure that includes three or more levels, and/or the lattice structure may include three or more levels (e.g., three or more support layers 220). In some implementations, the number of temporary molding layers may be equal to the number of levels and/or support layers in the lattice structure. For example, if there are exactly three support layers 220 (e.g., if the lattice structure includes exactly three levels), then there may be exactly three temporary molding layers, as shown. As another example, if there are exactly four support layers 220 (e.g., if the lattice structure includes exactly four levels), then there may be exactly four temporary molding layers.

The hard mask layer 560 may be a semiconductor and may comprise, consist of, or consist essentially of semiconductive material. The semiconductive material may comprise, consist of, or consist essentially of boron-doped carbon or another suitable semiconductive material, among other examples. For compatibility with subsequent stages of the process 500, the hard mask layer 560 may have a thickness D7 of approximately 2000 Å, among other examples. However, other values and/or ranges for the thickness D7 are within the scope of the present disclosure.

The temporary molding layer 565 may be an electrical insulator and may comprise, consist of, or consist essentially of insulative material. The insulative material may comprise, consist of, or consist essentially of tetraethyl orthosilicate (TEOS) or another suitable insulative material, among other examples. For compatibility with subsequent stages of the process 500, and as an example, the temporary molding layer 565 may have a thickness that is equivalent to the separation distance D8 of approximately 3100 Å. However, other values and/or ranges for the thickness of the temporary molding layer 565 are within the scope of the present disclosure.

The temporary molding layer 575 may be an electrical insulator and may comprise, consist of, or consist essentially of insulative material. The insulative material may comprise, consist of, or consist essentially of borophosphosilicate glass (BPSG) or another suitable insulative material, among other examples. For compatibility with subsequent stages of the process 500, and as an example, the temporary molding layer 575 may have a thickness that is equivalent to the separation distance D3 of approximately 2600 Å (e.g., the separation distance D3 as described in connection with FIG. 2). However, other values and/or ranges for the thickness of the temporary molding layer 575 are within the scope of the present disclosure.

As shown in FIG. 5A, and at stage 510, the process 500 may include removing the hard mask layer 560 to expose the temporary molding layer 565. As an example, and in some implementations, removing the hard mask layer 560 may include using a planarization tool to perform a chemical-mechanical planarization (CMP) operation to remove hard mask layer 560. In some implementations, removing the hard mask layer 560 may include removing a portion of the temporary molding layer 565. After the portion of the temporary molding layer 565 is removed, the temporary molding layer 565 may have a thickness D9 that is reduced to approximately 2900 Å. However, other values and ranges for the thickness D9 are within the scope of the present disclosure.

As shown in FIG. 5A, and at stage 515, the process 500 may include removing a portion of the temporary molding layer 565 to thin the temporary molding layer 565 and to expose tips 580 of the electrode structure 205 (e.g., including tips of the concentric, conductive layers 210-1 and 210-2). As an example, and in some implementations, removing the portion of the temporary molding layer 565 may include using an etch tool to perform an etch operation that recesses the temporary molding layer 565 to expose the tips 580. After the portion is removed, the temporary molding layer 565 may have a thickness that is equivalent to the separation distance D1 of approximately 2600 Å (e.g., the separation distance D1 as described in connection with FIG. 2).

As shown in FIG. 5B, and at stage 520, the process 500 may include forming an insulative layer 585 (e.g., a conformal insulative layer) over and/or on the temporary molding layer 565 and the tips 580 of the electrode structure 205. As an example, and in some implementations, forming the insulative layer 585 may include using a deposition tool to perform an atomic layer deposition operation that deposits the insulative layer 585 over and/or on the temporary molding layer 565 and the tips 580. The insulative layer 585 may be an electrical insulator and may comprise, consist of, or consist essentially of insulative material. The insulative material may comprise, consist of, or consist essentially of silicon nitride, silicon dioxide, or another suitable insulative material, among other examples.

As shown in FIG. 5B, and at stage 525, the process 500 may include removing portions of the insulative layer 585 to form the capping structure 225 and the cavity 230 that passes through the capping structure 225 and between the tips 580. As an example, in some implementations, removing portions of the insulative layer 585 may include using a deposition tool, a photolithography tool, and an etch tool to perform a series of operations that form and pattern one or more masks over the insulative layer 585 and remove the portions of the insulative layer 585 through openings in the masks to form the capping structure 225 and the cavity 230.

As shown in FIG. 5B, and at stage 530, the process 500 may include removing the temporary molding layer 565 to expose the support layer 220-1 (e.g., an upper support layer). As an example, in some implementations, removing the temporary molding layer 565 (e.g., an upper temporary molding layer) may include using an etch tool to perform an exhuming operation to remove the temporary molding layer 565.

As shown in FIG. 5C, and at stage 535, the process 500 may include removing portions of the support layer 220-1. Removing the portions may include removing a portion of the support layer 220-1 between the conductive, concentric layers 210-1 and 210-2 to punch through to the temporary molding layer 575 (e.g., a middle temporary molding layer of the temporary molding layers 565, 570, and 575). As an example, in some implementations, removing portions of the support layer 220-1 may include using a deposition tool, a photolithography tool, and/or an etch tool to perform a series of operations that form and pattern one or more masks over the support layer 220-1 and remove the portions of the support layer 220-1 through openings in the one or more masks to punch through to the temporary molding layer 575.

As shown in FIG. 5C, and at stage 540, the process 500 may include removing the temporary molding layer 570 and the temporary molding layer 575 to expose co-facing surfaces of the concentric, conductive layers 210-1 and 210-2 to reveal the electrode structure 205. As an example, in some implementations, removing the temporary molding layer 570 and the temporary molding layer 575 may include using an etch tool to perform a dry etch operation that exhumes the temporary molding layer 570 and the temporary molding layer 575. As shown in FIG. 5C at stage 540, the electrode structure 205, including the concentric, conductive layers 210-1 and 210-2, remains supported by the tri-level lattice structure 215.

As shown in FIG. 5D, and at stage 545, the process 500 may include forming the capacitor dielectric 235 (e.g., a conformal layer of an insulative material) that passes through the cavity 230 and through the support layer 220-1, and that includes portions over, on, and/or along surfaces of the concentric, conductive layers 210-1 and 210-2. As an example, in some implementations, forming the capacitor dielectric 235 may include using a deposition tool to perform a chemical vapor deposition operation or a physical vapor deposition operation that deposits the capacitor dielectric 235.

As shown in FIG. 5D, and at stage 550, the process 500 may include forming the electrode structure 240 (e.g., a conformal layer of a conductive material) over and/or along surfaces of the capacitor dielectric 235. As an example, in some implementations, forming the electrode structure 240 may include using a deposition tool to perform a vapor deposition operation, a physical deposition operation, a sputtering operation, or a plating operation that deposits the electrode structure 240 over and/or along the surfaces of the capacitor dielectric 235.

As shown in FIG. 5D, and at stage 555, the process may include forming the insulative fill 245 over and/or along surfaces of the capping structure 225, the support layers 220-1 through 220-3, and/or the electrode structure 240. As an example, in some implementations, forming the insulative fill may include using a deposition tool to perform a chemical vapor deposition operation or a physical deposition operation that forms the insulative fill.

As indicated above, the process steps described in connection with FIGS. 5A-5D are provided as examples. Other examples may differ from what is described with respect to FIGS. 5A-5D. Furthermore, the structure shown at stage 555 may be equivalent to the capacitor structure 200-1 described elsewhere herein.

FIGS. 6A-6D are diagrammatic views showing formation of the capacitor structure 200-2 using an example process 600 described herein. The process 600 includes stages 605, 610,. 655. In some implementations, the example process 600 described below in connection with FIGS. 6A-6D may correspond to the method 400 and/or one or more blocks of the method 400. However, the process described below is an example, and other example processes may be used to form the structure capacitor structure 200-2, an integrated assembly that includes the structure capacitor structure 200-2, and/or one or more parts of the structure capacitor structure 200-2 and/or the integrated assembly.

As shown in FIG. 6A, and at stage 605, the process 600 may include receiving a multi-layer stack including a hard mask layer 660. In some implementations, and as described in greater detail in connection with stages 610-655, the hard mask layer 660 may perform as a temporary molding layer.

Below the hard mask layer 660, the multi-layer stack may include the tri-level lattice structure 215, including the support layers 220-1 through 220-3. Furthermore, the multi-layer stack may include a temporary molding layer 665 and a temporary molding layer 670 (e.g., two temporary molding layers) that are interspersed with the tri-level lattice structure 215 (e.g., interspersed with the support layers 220-1 through 220-3). The multi-layer stack may include the electrode structure 205 including the concentric, conductive layers 210-1 and 210-2 that penetrate through the hard mask layer 660, the temporary molding layer 665, and the temporary molding layer 670.

Although the multi-layer stack is shown as including a tri-level lattice structure having three levels (e.g., exactly three levels), in some implementations, the multi-layer stack may include a lattice structure that includes more than three levels. Thus, the multi-layer stack may include a lattice structure that includes three or more levels, and/or the lattice structure may include three or more levels (e.g., three or more support layers 220). In some implementations, the number of temporary molding layers may be equal to one less than the number of levels and/or support layers in the lattice structure. For example, if there are exactly three support layers 220 (e.g., if the lattice structure includes exactly three levels), then there may be exactly two temporary molding layers, as shown. As another example, if there are exactly four support layers 220 (e.g., if the lattice structure includes exactly four levels), then there may be exactly three temporary molding layers.

The hard mask layer 660 may be a semiconductor and may comprise, consist of, or consist essentially of semiconductive material. The semiconductive material may comprise, consist of, or consist essentially of boron-doped carbon or another suitable semiconductive material, among other examples. For compatibility with subsequent stages of the process 600, the hard mask layer 660 may have a thickness D10 of approximately 2000 Å, among other examples. However, other values and/or ranges for the thickness D10 are within the scope of the present disclosure.

The temporary molding layer 665 may be an electrical insulator and may comprise, consist of, or consist essentially of insulative material. The insulative material may comprise, consist of, or consist essentially of tetraethyl orthosilicate (TEOS) or another suitable insulative material, among other examples. For compatibility with subsequent stages of the process 600, and as an example, the temporary molding layer 665 may have a thickness that is equivalent to the separation distance D5 of approximately 3600 Å (e.g., the separation distance D5 as described in connection with FIG. 2). However, other values and/or ranges for the thickness of the temporary molding layer 665 are within the scope of the present disclosure.

The temporary molding layer 670 may be an electrical insulator and may comprise, consist of, or consist essentially of insulative material. The insulative material may comprise, consist of, or consist essentially of borophosphosilicate glass (BPSG) or another suitable insulative material, among other examples. For compatibility with subsequent stages of the process 600, and as an example, the temporary molding layer 670 may have a thickness that is equivalent to the separation distance D6 of approximately 3100 Å (e.g., the separation distance D6 as described in connection with FIG. 2). However, other values and/or ranges for the thickness of the temporary molding layer 670 are within the scope of the present disclosure.

As shown in FIG. 6A, and at stage 610, the process 600 may include removing a first portion of the hard mask layer 660 to planarize the hard mask layer 660. As an example, and in some implementations, removing the first portion of the hard mask layer 660 may include using a planarization tool to perform a chemical-mechanical planarization (CMP) operation to planarize the hard mask layer 660. After removing the first portion, the hard mask layer 660 may have a thickness D11 that is reduced to approximately 1800 Å. However, other values and/or ranges for the thickness D11 are within the scope of the present disclosure.

As shown in FIG. 6A, and at stage 615, the process 600 may include removing a second portion of the hard mask layer 660 to thin the hard mask layer 660 and to expose tips 675 of electrode structure 205 (e.g., including tips of the concentric, conductive layers 210-1 and 210-2). As an example, and in some implementations, removing the second portion of the hard mask layer 660 may include using an etch tool to perform an etch operation that recesses the hard mask layer 660 to expose the tips 675. After the second portion is removed, the hard mask layer 660 may have a thickness D12 that is reduced to approximately 1800 Å. However, other values and/or ranges for the thickness D12 are within the scope of the present disclosure.

As shown in FIG. 6B, and at stage 620, the process 600 may include forming an insulative layer 680 (e.g., a conformal insulative layer) over and/or on the hard mask layer 660 and the tips 675 of the electrode structure 205. As an example, and in some implementations, forming the insulative layer 680 may include using a deposition tool to perform an atomic layer deposition operation that deposits the insulative layer 680 over and/or on the hard mask layer 660 and the tips 675. The insulative layer 680 may be an electrical insulator and may comprise, consist of, or consist essentially of insulative material. The insulative material may comprise, consist of, or consist essentially of silicon nitride, silicon dioxide, or another suitable insulative material, among other examples.

As shown in FIG. 6B, and at stage 625, the process 600 may include removing portions of the insulative layer 680 to form the capping structure 225 and the cavity 230 that passes through the capping structure 225 and between the tips 675. As an example, in some implementations, removing portions of the insulative layer 680 may include using a deposition tool, a photolithography tool, and an etch tool to perform a series of operations that form and pattern one or more masks over the insulative layer 680 and remove the portions of the hard mask layer 660 through openings in the masks to form the capping structure 225 and the cavity 230.

As shown in FIG. 6B, and at stage 630, the process 600 may include removing a third, remaining portion of hard mask layer 660 to expose the support layer 220-1 (e.g., an upper support layer). As an example, and in some implementations, removing the hard mask layer 660 (e.g., an upper temporary molding layer) may include using an etch tool to perform a vapor etching operation to remove the hard mask layer 660.

As shown in FIG. 6C, and at stage 635, the process 600 may include removing portions of the support layer 220-1. Removing the portions may include removing a portion of the support layer 220-1 between the conductive, concentric layers 210-1 and 210-2 to punch through to the temporary molding layer 665 (e.g., an upper temporary molding layer of the temporary molding layers 665 and 670). As an example, in some implementations, removing portions of the support layer 220-1 may include using a deposition tool, a photolithography tool, and/or an etch tool to perform a series of operations that form and pattern one or more masks over the support layer 220-1 and remove the portions of the support layer 220-1 through openings in the one or more masks to punch through to the temporary molding layer 665.

As shown in FIG. 6C, and at stage 640, the process 600 may include removing the temporary molding layer 665 and the temporary molding layer 670 to expose co-facing surfaces of the concentric, conductive layers 210-1 and 210-2 to reveal the electrode structure 205. As an example, in some implementations, removing the temporary molding layer 665 and the temporary molding layer 670 may include using an etch tool to perform a dry etch operation that exhumes the temporary molding layer 665 and the temporary molding layer 670. As shown in FIG. 6C at stage 640, the electrode structure 205, including the concentric, conductive layers 210-1 and 210-2, remains supported by the tri-level lattice structure 215.

As shown in FIG. 6D, and at stage 645, the process 600 may include forming the capacitor dielectric 235 (e.g., a conformal layer of an insulative material) that passes through the cavity 230 and through the support layer 220-1 and that includes portions over, on, and/or along surfaces of the concentric, conductive layers 210-1 and 210-2. As an example, and in some implementations, forming the capacitor dielectric 235 may include using a deposition tool to perform a chemical vapor deposition operation or a physical vapor deposition operation that deposits the capacitor dielectric 235.

As shown in FIG. 6D, and at stage 650, the process 600 may include forming the electrode structure 240 (e.g., a conformal layer of a conductive material) over and/or along surfaces of the capacitor dielectric 235. As an example, in some implementations, forming the electrode structure 240 may include using a deposition tool to perform a vapor deposition operation, a physical deposition operation, a sputtering operation, or a plating operation that deposits the electrode structure 240 over and/or along the surfaces of the capacitor dielectric 235.

As shown in FIG. 6D, and at stage 655, the process 600 may include forming the insulative fill 245 over and/or along surfaces of the capping structure 225, the support layers 220-1 through 220-3, and/or the electrode structure 240. As an example, in some implementations, forming the insulative fill may include using a deposition tool to perform a chemical vapor deposition operation or a physical deposition operation that forms the insulative fill.

As indicated above, the process steps described in connection with FIGS. 6A-6D are provided as examples. Other examples may differ from what is described with respect to FIGS. 6A-6D. Furthermore, the structure shown at stage 655 may be equivalent to the capacitor structure 200-2 described elsewhere herein.

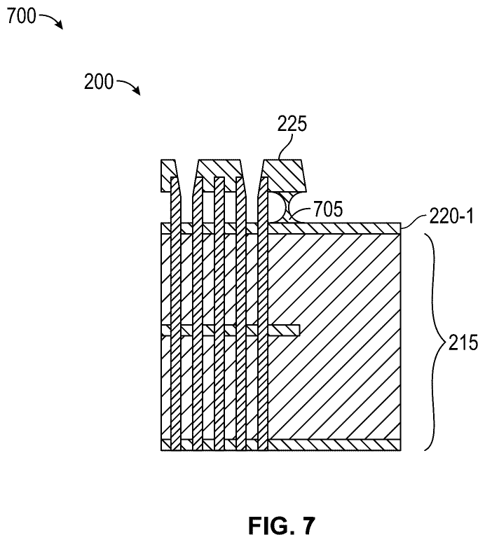

FIG. 7 is a diagrammatic view of an example implementation 700 described herein. In some implementations, and as shown in FIG. 7, an operation used to remove a hard mask during formation of a capacitor structure (e.g., a vapor etching operation that removes the hard mask layer 660 as described in connection with FIG. 6B) may be incomplete, and a remnant 705 of the hard mask (e.g., boron-doped carbon) may be between a capping structure (e.g., the capping structure 225) and an upper support layer of a tri-level lattice structure (e.g., the support layer 220-1 of the tri-level lattice structure 215).

As indicated above, FIG. 7 is provided as an example. Other examples may differ from what is described with regard to FIG. 7.

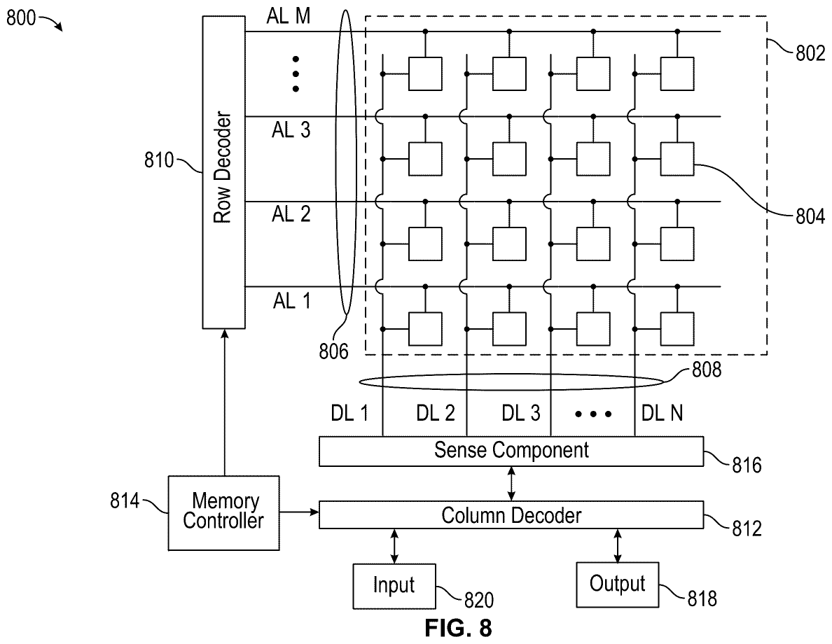

FIG. 8 is a diagrammatic view of an example memory device 800 described herein. The memory device 800 may include a memory array 802 that includes multiple memory cells 804. A memory cell 804 is programmable or configurable into a data state of multiple data states (e.g., two or more data states). For example, a memory cell 804 may be set to a particular data state at a particular time, and the memory cell 804 may be set to another data state at another time. A data state may correspond to a value stored by the memory cell 804. The value may be a binary value, such as a binary 0 or a binary 1, or may be a fractional value, such as 0.5, 1.5, or the like. A memory cell 804 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 804 by activating or selecting the appropriate access line 806 (shown as access lines AL 1 through AL M) and digit line 808 (shown as digit lines DL 1 through DL N). An access line 806 may also be referred to as a “row line” or a “word line,” and a digit line 808 may also be referred to a “column line” or a “bit line.” Activating or selecting an access line 806 or a digit line 808 may include applying a voltage to the respective line. An access line 806 and/or a digit line 808 may comprise, consist of, or consist essentially of a conductive material, such as a metal (e.g., copper, aluminum, gold, titanium, or tungsten) and/or a metal alloy, among other examples. In FIG. 8, each row of memory cells 804 is connected to a single access line 806, and each column of memory cells 804 is connected to a single digit line 808. By activating one access line 806 and one digit line 808 (e.g., applying a voltage to the access line 806 and digit line 808), a single memory cell 804 may be accessed at (e.g., is accessible via) the intersection of the access line 806 and the digit line 808. The intersection of the access line 806 and the digit line 808 may be called an “address” of a memory cell 804.

In some implementations, the logic storing device of a memory cell 804, such as a capacitor, may be electrically isolated from a corresponding digit line 808 by a selection component, such as a transistor. The access line 806 may be connected to and may control the selection component. For example, the selection component may be a transistor, and the access line 806 may be connected to the gate of the transistor. Activating the access line 806 results in an electrical connection or closed circuit between the capacitor of a memory cell 804 and a corresponding digit line 808. The digit line 808 may then be accessed (e.g., is accessible) to either read from or write to the memory cell 804.

A row decoder 810 and a column decoder 812 may control access to memory cells 804. For example, the row decoder 810 may receive a row address from a memory controller 814 and may activate the appropriate access line 806 based on the received row address. Similarly, the column decoder 812 may receive a column address from the memory controller 814 and may activate the appropriate digit line 808 based on the column address.

Upon accessing a memory cell 804, the memory cell 804 may be read (e.g., sensed) by a sense component 816 to determine the stored data state of the memory cell 804. For example, after accessing the memory cell 804, the capacitor of the memory cell 804 may discharge onto its corresponding digit line 808. Discharging the capacitor may be based on biasing, or applying a voltage, to the capacitor. The discharging may induce a change in the voltage of the digit line 808, which the sense component 816 may compare to a reference voltage (not shown) to determine the stored data state of the memory cell 804. For example, if the digit line 808 has a higher voltage than the reference voltage, then the sense component 816 may determine that the stored data state of the memory cell 804 corresponds to a first value, such as a binary 1. Conversely, if the digit line 808 has a lower voltage than the reference voltage, then the sense component 816 may determine that the stored data state of the memory cell 804 corresponds to a second value, such as a binary 0. The detected data state of the memory cell 804 may then be output (e.g., via the column decoder 812) to an output component 818 (e.g., a data buffer). A memory cell 804 may be written (e.g., set) by activating the appropriate access line 806 and digit line 808. The column decoder 812 may receive data, such as input from input component 820, to be written to one or more memory cells 804. A memory cell 804 may be written by applying a voltage across the capacitor of the memory cell 804.

The memory controller 814 may control the operation (e.g., read, write, re-write, refresh, and/or recovery) of the memory cells 804 via the row decoder 810, the column decoder 812, and/or the sense component 816. The memory controller 814 may generate row address signals and column address signals to activate the desired access line 806 and digit line 808. The memory controller 814 may also generate and control various voltages used during the operation of the memory array 802.

In some implementations, the memory device 800 includes the capacitor structure 200 (e.g., the capacitor structure 200-1 and/or the capacitor structure 200-2), and/or an integrated assembly that includes the capacitor structure 200. For example, the memory array 802 may include the capacitor structure 200, and/or an integrated assembly that includes the capacitor structure 200. Additionally, or alternatively, the memory cell 804 may include a memory cell described elsewhere herein.

As indicated above, FIG. 8 is provided as an example. Other examples may differ from what is described with respect to FIG. 8.

In some implementations, an integrated assembly includes a first capacitor electrode structure comprising concentric, conductive layers that are vertically arranged; a lattice structure, having at least three levels, that conjoins with the concentric, conductive layers, that is laterally arranged, and that provides mechanical support to the first capacitor electrode structure; a capping structure on tips of the concentric, conductive layers; a capacitor dielectric that passes through the capping structure, that passes through a support layer of the lattice structure, and that conjoins with surfaces of the concentric, conductive layers; and a second capacitor electrode structure that conjoins with the capacitor dielectric.

In some implementations, a method includes receiving a multi-layer stack including a hard mask layer, a stack of at least three temporary molding layers that are interspersed with a lattice structure, having at least three levels, below the hard mask layer, and concentric, conductive layers that penetrate through the hard mask layer and through the at least three temporary molding layers; removing the hard mask layer to expose an upper temporary molding layer of the at least three temporary molding layers; forming a recess in the upper temporary molding layer to expose tips of the concentric, conductive layers; forming an insulative layer over the upper temporary molding layer and the tips of the concentric, conductive layers; forming a cavity that extends through the hard mask layer and between the tips; removing the upper temporary molding layer; removing a portion of an upper support layer, of the lattice structure, to punch through the upper support layer to a middle temporary molding layer of the stack of at least three temporary molding layers, wherein the portion is between co-facing surfaces of the conductive, concentric layers; and removing the middle temporary molding layer and a lower temporary molding layer, of the stack of at least three temporary molding layers, to expose co-facing surfaces of the concentric, conductive layers, wherein the concentric, conductive layers remain supported by the lattice structure.

In some implementations, a method includes receiving a multi-layer stack including a hard mask layer, a stack of temporary molding layers that are interspersed with a lattice structure, having at least three levels, below the hard mask layer, and concentric, conductive layers that penetrate through the hard mask layer and the temporary molding layers, wherein the multi-layer stack includes a number of temporary molding layers that is one less than a number of levels included in the lattice structure; removing a first portion of the hard mask layer to planarize the hard mask layer; removing a second portion of the hard mask layer to thin the hard mask layer and expose tips of the concentric, conductive layers; forming an insulative layer over the hard mask layer and the tips; forming a cavity that extends through the hard mask layer between the tips; removing a third, remaining portion of the hard mask layer; removing a portion of an upper support layer, of the lattice structure, to punch through the upper support layer to an upper temporary molding layer of the temporary molding layers, wherein the portion is between co-facing surfaces of the conductive, concentric layers; and removing the upper temporary molding layer and a lower temporary molding layer, of the temporary molding layers, to expose co-facing surfaces of the concentric, conductive layers, wherein the concentric, conductive layers remain supported by the lattice structure.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first capacitor electrode structure comprising concentric, conductive layers that are vertically arranged;
a lattice structure, having at least three levels, that conjoins with the concentric, conductive layers, that is laterally arranged, and that provides mechanical support to the first capacitor electrode structure;
a capping structure on tips of the concentric, conductive layers;
a capacitor dielectric that passes through the capping structure, that passes through a support layer of the lattice structure, and that conjoins with surfaces of the concentric, conductive layers; and
a second capacitor electrode structure that conjoins with the capacitor dielectric.

2. The integrated assembly of claim 1, wherein the lattice structure comprises:
an upper support layer,
a lower support layer, and
a middle support layer between the upper support layer and the lower support layer.

3. The integrated assembly of claim 2, wherein a first separation distance between the capping structure and the upper support layer and a second separation distance between the upper support layer and the middle support layer are a same approximate separation distance.

4. The integrated assembly of claim 3, wherein a third separation distance between the middle support layer and the lower support layer is a same approximate separation distance as the first separation distance and the second separation distance.

5. The integrated assembly of claim 2, wherein a first separation distance between the capping structure and the upper support layer is less than a second separation distance between the upper support layer and the middle support layer.

6. The integrated assembly of claim 5, wherein a third separation distance between the middle support layer and the lower support layer is less than the second separation distance.

7. The integrated assembly of claim 6, wherein the third separation distance is greater than the first separation distance.

8. The integrated assembly of claim 2, further comprising:
boron-doped carbon between the capping structure and the upper support layer.

9. The integrated assembly of claim 1, wherein the lattice structure has exactly three levels.

10. A method, comprising:
receiving a multi-layer stack including a hard mask layer, a stack of at least three temporary molding layers that are interspersed with a lattice structure, having at least three levels, below the hard mask layer, and concentric, conductive layers that penetrate through the hard mask layer and through the at least three temporary molding layers;
removing the hard mask layer to expose an upper temporary molding layer of the at least three temporary molding layers;
forming a recess in the upper temporary molding layer to expose tips of the concentric, conductive layers;
forming an insulative layer over the upper temporary molding layer and the tips of the concentric, conductive layers;
forming a cavity that extends through the hard mask layer and between the tips;
removing the upper temporary molding layer;
removing a portion of an upper support layer, of the lattice structure, to punch through the upper support layer to a middle temporary molding layer of the stack of at least three temporary molding layers,
wherein the portion is between co-facing surfaces of the conductive, concentric layers; and
removing the middle temporary molding layer and a lower temporary molding layer, of the stack of at least three temporary molding layers, to expose co-facing surfaces of the concentric, conductive layers,
wherein the concentric, conductive layers remain supported by the lattice structure.

11. The method of claim 10, wherein at least one of:
the hard mask layer includes boron-doped carbon,
the upper temporary molding layer includes tetraethyl orthosilicate,
the middle temporary molding layer includes tetraethyl orthosilicate, or
the lower temporary molding layer includes boron phosphosilicate glass.

12. The method of claim 10, wherein removing the hard mask layer includes:
using a chemical-mechanical planarization operation that removes an entirety of the hard mask layer and portions of the conductive, concentric layers.

13. The method of claim 10, wherein forming the cavity includes:
forming a patterned mask over the hard mask layer, and
etching the hard mask layer using the patterned mask to remove portions of the hard mask layer through openings in the patterned mask.

14. The method of claim 10, wherein there are exactly three temporary molding layers in the multi-layer stack, and wherein the lattice structure has exactly three levels.

15. A method, comprising:
receiving a multi-layer stack including a hard mask layer, a stack of temporary molding layers that are interspersed with a lattice structure, having at least three levels, below the hard mask layer, and concentric, conductive layers that penetrate through the hard mask layer and the temporary molding layers,
wherein the multi-layer stack includes a number of temporary molding layers that is one less than a number of levels included in the lattice structure;
removing a first portion of the hard mask layer to planarize the hard mask layer;
removing a second portion of the hard mask layer to thin the hard mask layer and expose tips of the concentric, conductive layers;
forming an insulative layer over the hard mask layer and the tips;
forming a cavity that extends through the hard mask layer between the tips;
removing a third, remaining portion of the hard mask layer;
removing a portion of an upper support layer, of the lattice structure, to punch through the upper support layer to an upper temporary molding layer of the temporary molding layers,
wherein the portion is between co-facing surfaces of the conductive, concentric layers; and
removing the upper temporary molding layer and a lower temporary molding layer, of the temporary molding layers, to expose co-facing surfaces of the concentric, conductive layers,
wherein the concentric, conductive layers remain supported by the lattice structure.

16. The method of claim 15, wherein at least one of:
the hard mask layer includes boron-doped carbon,
the upper temporary molding layer includes tetraethyl orthosilicate, or
the lower temporary molding layer includes boron phosphosilicate glass.

17. The method of claim 15, wherein removing the first portion of the hard mask layer includes:
using a chemical-planarization operation that buffs the hard mask layer and planarizes the hard mask layer.

18. The method of claim 15, wherein removing the second portion of the hard mask layer includes:
using a wet etch operation, a plasma-based etch operation, or an ion-based etch operation to remove the second portion.

19. The method of claim 15, wherein removing the third, remaining portion of the hard mask layer includes:
using a vapor-based etch operation to remove the third, remaining portion.

20. The method of claim 15, wherein there are exactly two temporary molding layers in the multi-layer stack, and wherein the lattice structure has exactly three levels.
